(19) United States
(12) Patent Application Publication
(10) Pub. No.: US 2008/0061796 A1
(43) Pub. Date: Mar. 13, 2008

(54) SIGNAL DETECTING APPARATUS AND SIGNAL DETECTING SYSTEM

(75) Inventors: Yasuo TAKADA, TOKYO (JP); Tsuyohiro IHATA, TOKYO (JP)

Correspondence Address: SUGHRUE MION, PLLC, 2100 PENNSYLVANIA AVENUE, N.W., SUITE 800, WASHINGTON, DC, 20037, US

(73) Assignee: ADVANTEST CORPORATION

(21) Appl. No.: 11/926,740

(22) Filed: Oct. 29, 2007

Related U.S. Application Data
(62) Division of application No. 11/443,007, filed on May 31, 2006.

(51) Int. Cl. G01R 19/165; G01R 31/00

(52) U.S. Cl. 324/555

(57) ABSTRACT

A signal detecting apparatus includes a component extractor extracting a voltage component whose absolute value is not less than a predetermined value from an electronic signal generated by a tester for testing an electric property of a device under test; a rate-of-change calculator calculating a time rate-of-change of a level of the voltage component extracted by the component extractor; a determiner determining whether the voltage component is identified as an irregular signal having a sudden change in voltage, based on the time rate-of-change calculated by the rate-of-change calculator; and a notifier notifying a user of a result of determination when the determiner determines that the voltage component is identified as the irregular signal.

This is a divisional of application Ser. No. 11/443,007 filed May 31, 2006. The entire disclosure(s) of the prior application(s), application Ser. No. 11/443,007 is considered part of the disclosure of the accompanying divisional application and is hereby incorporated by reference.

### BACKGROUND OF THE INVENTION

1. Field of the Invention

The present invention relates to a signal detecting apparatus for detecting an irregular signal in an electronic signal generated by a tester which tests the electric properties of a device under test (DUT), the irregular signal having a sudden change in voltage, and a signal detecting system using the signal detecting apparatus.

2. Description of the Related Art

A tester is used to test the electric properties of DUTs such as semiconductor devices. Current tester architecture generally includes a tester main frame and a test head. The tester main frame is configured to supply power to and generate test signals for a DUT. The test head is connected to the tester main frame via a specific cable and adapted to be electrically connected to the DUT, thereby transmitting a signal (e.g., test signal) output from the tester main frame to the DUT and transferring a response signal output from the DUT to the tester main frame. See Japanese Patent Application Laid-open No. H11-030647, for example.

The tester main frame has functions that store the patterns of the response signals in response to the test signals in advance as well as functions that generate and output various signals. The tester main frame thus compares a stored pattern with a pattern of a response signal output from a DUT, thereby testing the electric properties of the DUT to determine whether it is good or bad.

In conventional testers, however, an irregular signal having a sudden change in voltage (e.g., voltage spike), when added to a regular signal transmitted from the tester main frame to the DUT, adversely affects the DUT. This problem will be now described.

An irregular signal having a sudden change in voltage, especially having a peak voltage higher than a rated voltage of the DUT, when input to the DUT, may degrade the electric properties of the DUT or break down the DUT. Recent DUTs have fine circuit patterns, resulting in low voltage resistance. The DUTs are therefore designed with low rated voltage, and may be easily broken down when receiving the irregular signal. There is a strong possibility that the irregular signal has any effect on the DUT even when not breaking down it. For example, even though no degradation of performance is detected in a DUT by a tester, the life of the DUT product may decrease significantly.

Thus, conventional testers are in general designed so that there is no sudden change in voltage in signals generated by the tester main frame. However, it is very difficult to completely prevent a signal generated by the tester main frame from getting an irregular signal, due to an error in a program for controlling a tester main frame and defining the patterns of signals to be generated, aged deterioration of electronic circuits constituting the tester main frame, and the like.

Accordingly, the conventional testers detect an irregular signal through observation of signal waveforms with an oscilloscope after testing, so that a user checks whether a trouble such as a failure of a DUT is caused by the irregular signal. When an irregular signal is detected in a tester, the DUT whose electric properties are tested with the tester is tested again with another tester.

However, the conventional testers do not have any support for detecting an irregular signal. An irregular signal with a specific waveform does not break out the DUT, not triggering the observation of the waveform with an oscilloscope after testing. The irregular signal with the specific waveform is very difficult to be identified even with the oscilloscope. In other words, the conventional testers have a limited advantage that can identify the occurrence of an irregular signal after testing only when the DUT is broken down.

### SUMMARY OF THE INVENTION

A signal detecting apparatus according to one aspect of the present invention includes a component extractor extracting a voltage component whose absolute value is not less than a predetermined value from an electronic signal generated by a tester for testing an electric property of a device under test; a rate-of-change calculator calculating a time rate-of-change of a level of the voltage component extracted by the component extractor; a determiner determining whether the voltage component is identified as an irregular signal having a sudden change in voltage, based on the time rate-of-change calculated by the rate-of-change calculator; and a notifier notifying a user of a result of determination when the determiner determines that the voltage component is identified as the irregular signal.

A signal detecting system according to another aspect of the present invention includes a plurality of signal detecting apparatuses corresponding respectively to a plurality of testers. Each of the signal detecting apparatuses includes a component extractor extracting a voltage component whose absolute value is not less than a predetermined value from an electronic signal generated by a tester for testing an electric property of a device under test; a rate-of-change calculator calculating a time rate-of-change of a level of the voltage component extracted by the component extractor; and a determiner determining whether the voltage component is identified as an irregular signal having a sudden change in voltage, based on the time rate-of-change calculated by the rate-of-change calculator. The signal detecting system also includes a management server receiving results of determination by the signal detecting apparatuses, and notifying a user of at least one of the results which indicates that the voltage component is identified as the irregular signal.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a schematic diagram of a system including a signal detecting apparatus of a first embodiment according to the present invention;

FIG. 2 is a block diagram of the signal detecting apparatus;

FIG. 3 is a flowchart illustrating an operation of the signal detecting apparatus;

FIG. 4 is a graph showing time series data of a power supply signal and a time rate-of-change of the signal;

FIG. 5 is a block diagram of a signal detecting apparatus of a second embodiment according to the present invention;

FIG. 6 is a block diagram of a signal detecting apparatus of a third embodiment according to the present invention; and

FIG. 7 is a block diagram of a signal detecting system of a fourth embodiment according to the present invention.

### DETAILED DESCRIPTION OF THE PREFERRED EMBODIMENTS

Preferred embodiments of a signal detecting apparatus and a signal detecting system according to the invention will be described below. The following detailed description of the embodiments is not intended to limit the scope of the invention but it is merely representative of the presently preferred embodiments of the invention.

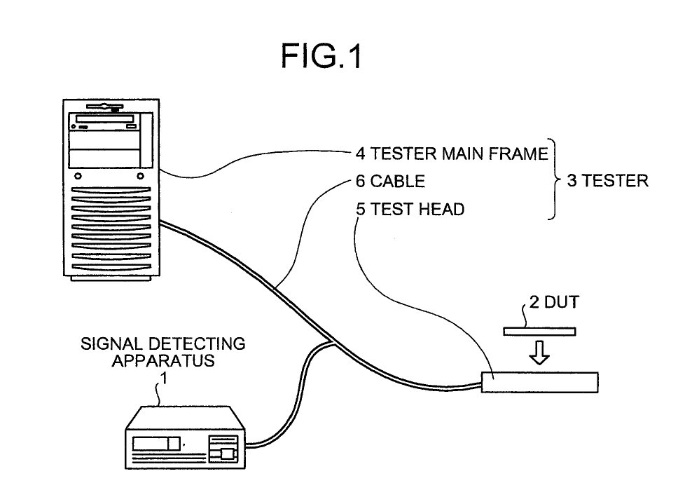

A first embodiment will be described first. FIG. 1 is a schematic diagram of a system including a signal detecting apparatus of the first embodiment. Referring to FIG. 1, a signal detecting apparatus 1 of the first embodiment detects an irregular signal in an electronic signal generated by a tester 3 which tests the electric properties of a device under test (DUT) 2 such as any electrical circuit. The irregular signal to be detected has a sudden change in voltage.

Specifically, the tester 3 is configured to be electrically connected to a tester main frame 4 which generates electronic signals and the DUT 2, and includes a test head 5 through which an electronic signal generated by the tester main frame 4 is transmitted to the DUT 2, and a cable 6 which electrically connects the tester main frame 4 and the test head 5.

The signal detecting apparatus 1 is configured to detect an irregular signal in an electronic signal transmitted from the tester main frame 4 to the test head 5, and connected to the cable 6. In the first embodiment, the electronic signal transmitted from the tester main frame 4 is a power supply signal serving as power for the DUT 2.

The tester main frame 4 is configured to generate an electronic signal for testing and analyze a response signal output from the DUT 2. In the first embodiment, the electronic signal for testing includes at least the power supply signal serving as power for the DUT 2.

The test head 5 includes a probe which is electrically connected to the DUT 2 (not shown in the figure), and is configured to be electrically connected to the cable 6. The configuration of the test head 5 allows electrical connection of the test main frame 4 and the DUT 2 via the cable 6, and signal input to and signal output from the DUT 2.

The cable 6 electrically connects the tester main frame 4 and the test head 5. The cable 6 is specifically configured to transmit the electronic signals generated by the tester main frame 4. In the first embodiment, the cable 6 transmits at least a power supply signal for powering the DUT 2 in testing.

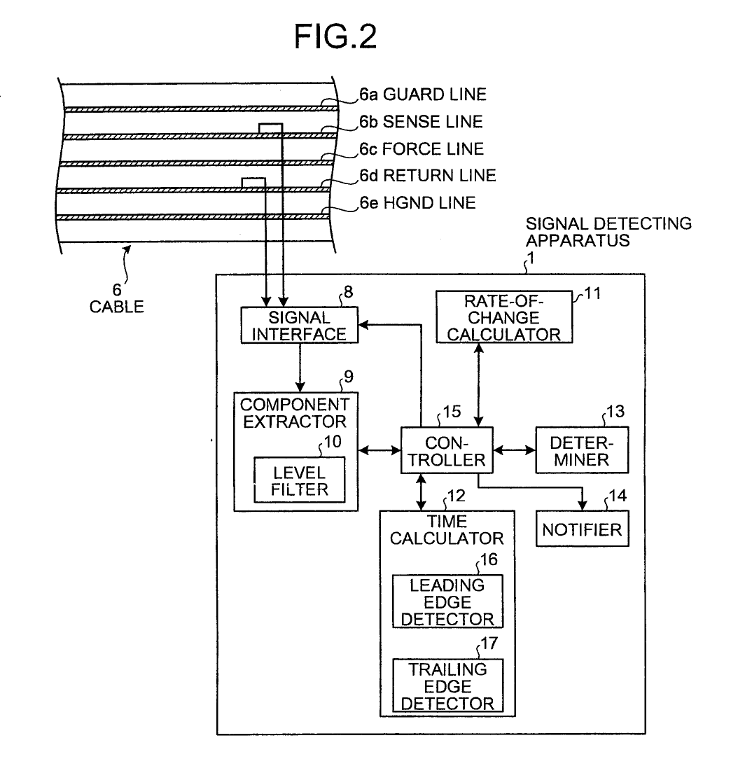

The configuration of the signal detecting apparatus 1 will then be described in detail. FIG. 2 is a block diagram of the signal detecting apparatus 1. Referring to FIG. 2, the signal detecting apparatus 1 includes a signal interface 8 which receives a power supply signal, which is an example of the electronic signal generated by the tester main frame 4, and a component extractor 9 which extracts a voltage component of more than a predetermined level. The signal detecting apparatus 1 also includes a rate-of-change calculator 11 which calculates a time rate-of-change of the level of the voltage component extracted by the component extractor 9, a time calculator 12 which calculates a time interval between a given point in a period of positive time rate-of-change of the level of the voltage component and a given point in a period of negative time rate-of-change of the level of the voltage component, a determiner 13 which determines whether the voltage component is identified as the irregular signal based on the time interval calculated by the time calculator 12, a notifier 14 which notifies of a result of determination by the determiner 13, and a controller 15 which controls the signal interface 8, the component extractor 9, the rate-of-change calculator 11, the time calculator 12, the determiner 13, and the notifier 14.

The signal interface 8 receives the power supply signal transmitted from the tester main frame 4 to the DUT 2 via the cable 6. Although various components may be used for receiving the signal, the signal interface 8 of the first embodiment is a general I/O interface and used together with, for example, a signal divider placed on the cable 6. The signal interface 8 of the first embodiment is also suitable for the structure of the cable 6, and specifically configured to receive the electronic signals (especially the power supply signal) transmitted over a sense line 6b and a return line 6d of five lines of the cable 6, the other lines being a guard line 6a, force line 6c, and an HGND line 6e (see FIG. 2).

The component extractor 9 extracts a voltage component whose absolute value is determined to be more than a predetermined threshold voltage. The component extractor 9 specifically includes a level filter 10 which passes a component, of the power supply signal received through the signal interface 8, whose absolute value is more than a predetermined threshold, and is configured to output the voltage component filtered by the level filter 10 to the controller 15. The threshold voltage of the level filter 10 is preferably a value that can have any effect on the DUT, e.g., a value that does not break down the DUT but reduces the life of the DUT product; such a value can be set depending on the DUT. The component extractor preferably amplifies the received signal (power supply signal) to a voltage level suitable for determination of whether it is the irregular signal.

The rate-of-change calculator 11 calculates a time rate-of-change of voltage in the voltage component extracted by the component extractor 9. Although any factor of the voltage component may be used as the time rate-of-change, the rate-of-change calculator 11 of the first embodiment calculates a time-deferential of the voltage component as an example of the time rate-of-change.

The time calculator 12 calculates a time interval between a given point in a period of positive time rate-of-change and a given point in a period of negative time rate-of-change, by using the time rate-of-changes of the voltage component calculated by the rate-of-change calculator 11. The time calculator 12 is specifically configured to serially receive the time rate-of-changes calculated by the rate-of-change calculator 11 as time series data, and includes a leading edge detector 16 which detects a leading edge of the time series data (i.e., timing when the time rate-of-change changes from zero to positive), and a trailing edge detector 17 which detects a trailing edge of the time series data (i.e., timing when the time rate-of-change changes from zero to negative). With this configuration, the time calculator 12 identifies the leading edge of the time rate-of-change as a given point in a period of positive time rate-of-change and the trailing edge of the time rate-of-change as a given point in a period of negative time rate-of-change, to calculate the time interval between both points, and outputs the result of calculation to the controller 15. Each of the leading edge detector 16 and the trailing edge detector 17 can be configured with a comparator.

The determiner 13 is configured to determine whether the voltage component extracted by the component extractor 9 is identified as the irregular signal based on the time rate-of-change of voltage level. The determiner 13 of the first embodiment specifically performs the determination process based on the time interval calculated by the time calculator 12, and more specifically determines that the voltage component is the irregular signal when the time interval is not more than a predetermined threshold smaller than the minimum value of the time interval for a normal signal contained in a predetermined power supply signal.

The notifier 14 notifies of a result of determination by the determiner 13, and is configured to notify a user of the signal detecting apparatus of the occurrence of an irregular signal when the determiner 13 determines that a voltage component is identified as the irregular signal. The notifier 14 may be configured with a display for visualizing the result of determination, or may be configured to notify of the result of determination with an alarm. If the signal detecting apparatus of the first embodiment is connected to a network such as the Internet, the notifier may be also configured to send an e-mail with the result of determination to the user terminal via the network.

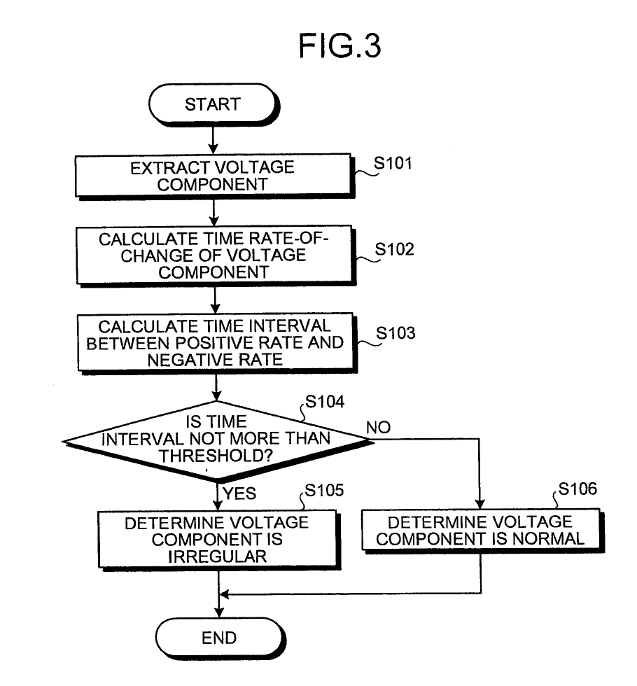

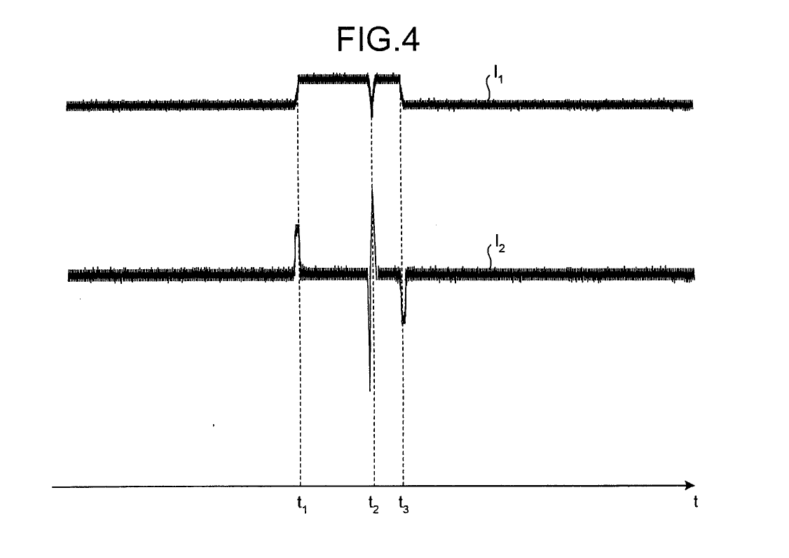

An operation of the signal detecting apparatus of the first embodiment will next be described with reference to FIGS. 3 and 4. FIG. 3 is a flowchart illustrating the operation of the signal detecting apparatus. FIG. 4 is a graph showing time series data of a power supply signal and a time rate-of-change of the signal.

In the signal detecting apparatus, the component extractor 9 first extracts a voltage component whose absolute value is more than a predetermined threshold from the power supply signal (step S101). The rate-of-change calculator 11 then calculates a time rate-of-change of voltage in the voltage component extracted (step S102). The time calculator 12 next calculates a time interval between a given point in a period of positive time rate-of-change and a given point in a period of negative time rate-of-change (step S103). In the first embodiment, the given points are a leading edge of the time rate-of-change and a trailing edge of the time rate-of-change, respectively, which are detected by the leading edge detector 16 and trailing edge detector 17.

The signal detecting apparatus 1 determines whether the time interval calculated by the determiner 13 at step 103 is not more than a predetermined threshold (step S104). When the time interval is not more than the threshold step S104, Yes), the determiner 13 determines that the voltage component is identified as the irregular signal (step S105), and the notifier 14 notifies of the result of determination. When the time interval is more than the threshold (step S104, No), the determiner 13 determines that the voltage component is a signal other than the irregular signal, e.g., a normal component contained in the power supply signal (step S106), and the notifier 14 notifies of the result of determination.

The process of step S101 is for removing a noise component, which is disadvantageous for the DUT 2, from the power supply signal. The signal detecting apparatus 1 of the first embodiment is for detecting an irregular signal having a change in voltage that does not break down the DUT but has any effect (e.g., reduction of DUT product life) on it, and thus not required to analyze a weak voltage component whose absolute value is smaller than the predetermined threshold.

The signal detecting apparatus 1 of the first embodiment, as described above, determines the occurrence of the irregular signal using a time interval between a given point in a period of positive time rate-of-change of the voltage component and a given point in a period of negative time rate-of-change of the voltage component. The mechanism of determination will be described in detail below.

FIG. 4 is a graph showing time changes in voltage level and time rate-of change of the power supply signal. In FIG. 4, curve l₁ represents time changes in voltage level of the power supply signal, and curve l₂ represents time changes in time rate-of change of the power supply signal. Normal components of the power supply signal generally consist of pulse signals; the irregular signal to be detected has a sudden change in voltage in the pulse signal. Referring to FIG. 4, the curve l₁ shows an irregular signal having a sudden change in voltage at time t₂, in addition to a leading edge of a pulse signal as a normal component at time t₁ and a trailing edge of the pulse signal at time t₃.

The signal detecting apparatus 1 of the first embodiment can separate the irregular signal from the normal component by using the time rate-of-change of voltage component and thus to detect the irregular signal. Referring to FIG. 4, the curve l2, i.e., the time changes in time rate-of change, shows a peak caused by the leading edge of the pulse signal at time t₁, a peak caused by the trailing edge of the pulse signal at time t₃, and a peak cause by the irregular signal at time t₂. Comparing the peaks of the curve l2, the time interval between the positive peak and the negative peak of the normal component is a large amount (t₃-t₁ in FIG. 4), whereas the time interval between the positive peak and the negative peak of the irregular signal is a slight amount. As such, since the irregular signal has a sudden change in voltage, in other words, a property that changes instantaneously and returns immediately, the time interval between the positive time rate-of-change and negative time rate-of-change of the irregular signal is slight.

The signal detecting apparatus 1 of the first embodiment detects the irregular signal by using the deference of time intervals. In other words, in the signal detecting apparatus 1 of the first embodiment, a time interval between a given point in a period of positive time rate-of-change and a given point in a period of negative time rate-of-change is calculated, and a threshold smaller than the calculated time interval is stored in the determiner 13, in advance. At step S104, the determiner 13 compares the time interval calculated at step S103 with the stored threshold, thereby determining that the voltage component extracted is the irregular signal or the normal component.

This determination of whether the voltage component is the irregular signal enables the signal detecting apparatus 1 of the first embodiment to accurately detect the irregular signal. As shown in the curve l₂ of FIG. 4, since the irregular signal having a sudden change in voltage is distinctly different from the normal component of the power supply signal consisting of pulse signals in time series pattern of time rate-of-change, the irregular signal can be easily identified, allowing accurate detection of the irregular signal with a simple configuration.

A second embodiment will be described below. A signal detecting apparatus of the second embodiment further includes a defection estimator which estimates a defective part of the tester main frame 4 that generates an electronic signal having an irregular signal, based on an occurrence pattern of the irregular signal detected.

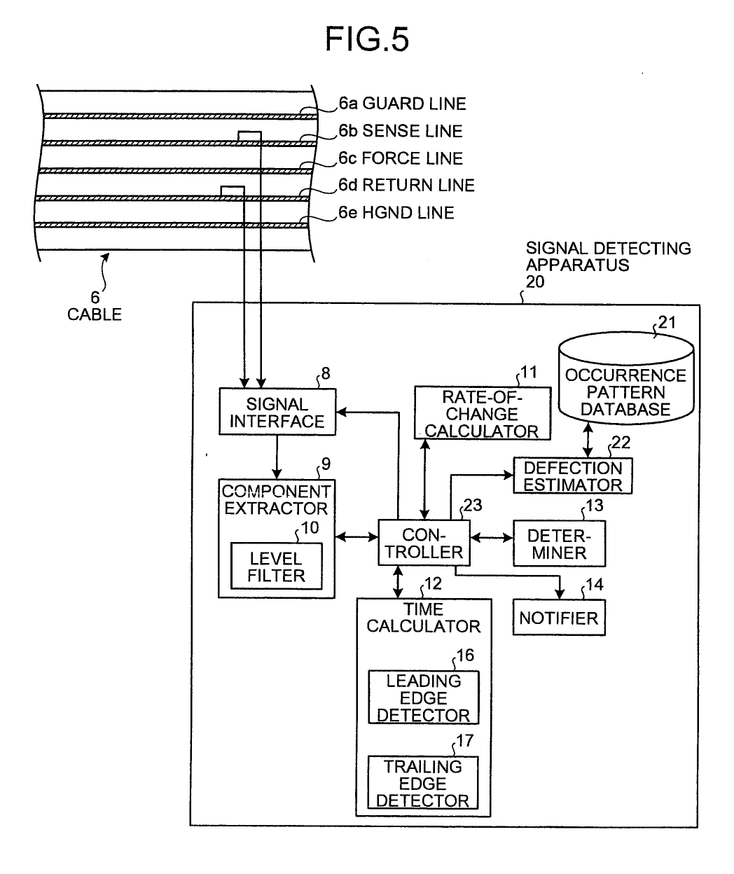

FIG. 5 is a block diagram of a signal detecting apparatus 20 of the second embodiment. Referring to FIG. 5, the signal detecting apparatus 20 includes the signal interface 8, component extractor 9, level filter 10, rate-of-change calculator 11, time calculator 12, determiner 13, notifier 14, leading edge detector 16, and trailing edge detector 17, like the signal detecting apparatus 1 of the first embodiment. In addition to these components, the signal detecting apparatus 20 includes an occurrence pattern database 21 where a relation between occurrence patterns of irregular signals and defective parts of testers is recorded, a defection estimator 22 which estimates a defective part based on the waveform of the detected irregular signal with reference to data recorded in the occurrence pattern database 21, and a controller 23 which controls the above components.

The occurrence pattern database 21 stores a relation between the occurrence patterns of the irregular signals occurring in testers having a common configuration before and defective parts of the testers. The occurrence patterns of irregular signals include, for example, the occurrence frequency of irregular signals and parameter on the waveform of the detected irregular signal such as peak voltage, half bandwidth, and waveform itself. Other data, if calculated from the detected irregular signal and available for the estimation of defective part, may be recorded as an occurrence pattern in the occurrence pattern database 21.

The defection estimator 22 estimates a defective part of the tester, which causes the irregular signal, based on the occurrence pattern of the irregular signal. The defection estimator 22 specifically is configured to determine the occurrence pattern of the voltage component determined to be identified as the irregular signal by the determiner 13, search the occurrence pattern database 21 for the same one as or one similar to the occurrence pattern determined, obtain information on a defective part associated with the same or similar occurrence pattern from the occurrence pattern database 21, and transmit the information to the controller 23. The information on the defective part obtained is transmitted to the notifier 14 via the controller 23; the notifier 14 notifies of the information as the estimation result of the defective part related to the detected irregular signal.

Since the irregular signal occurs due to an error in a program for defining the patterns of signals to be generated, aged deterioration of electronic circuits constituting the tester main frame, and the like, generally its occurrence pattern depends on such causes. Therefore, preparing a relation between the occurrence patterns of the irregular signals occurring in the same type of testers before and defective parts of the testers in the occurrence pattern database 21 in advance allows not only the detection of the irregular signal but also the estimation of a defective part of the tester. The occurrence pattern database 21 and the defection estimator 22 provides, to the signal detecting apparatus 20 of the second embodiment, a further advantage that can estimate a defective part of the tester when the irregular signal is detected and thus significantly reduce time required for repair, in addition to the advantages of the signal detecting apparatus of the first embodiment.

A third embodiment will be described below. A signal detecting apparatus of the third embodiment includes a repair determiner which determines whether the tester requires a repair, based on occurrence history of irregular signals.

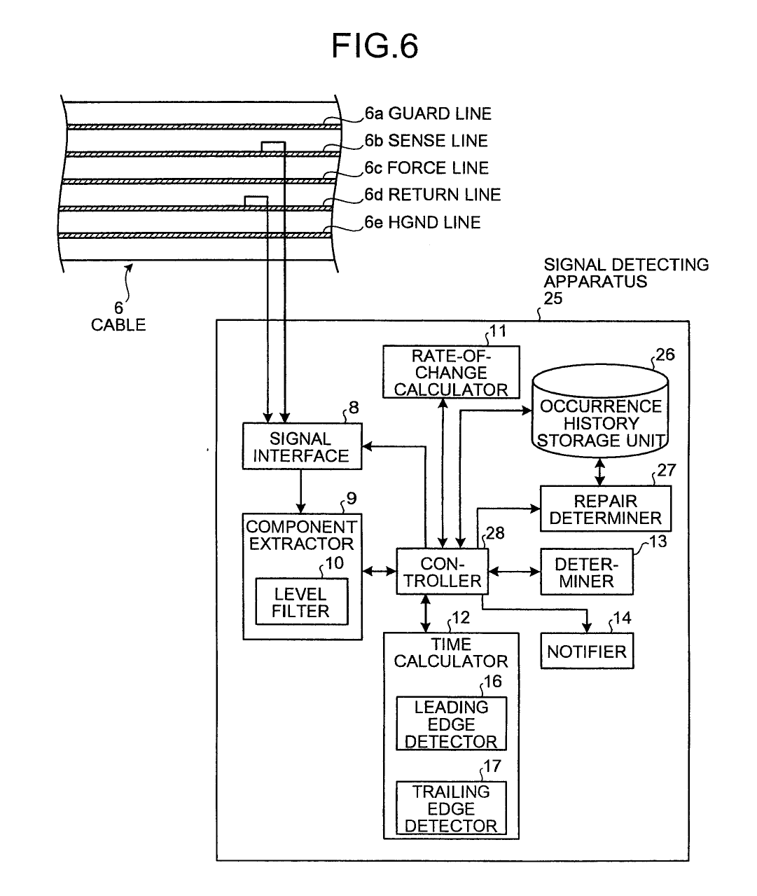

FIG. 6 is a block diagram of a signal detecting apparatus 25 of the third embodiment. Referring to FIG. 6, the signal detecting apparatus 25 includes the signal interface 8, component extractor 9, level filter 10, rate-of-change calculator 11, time calculator 12, determiner 13, notifier 14, leading edge detector 16, and trailing edge detector 17, like the signal detecting apparatus 1 of the first embodiment. In addition to these components, the signal detecting apparatus 25 includes an occurrence history storage unit 26 where occurrence history of the detected irregular signal is recorded, a repair determiner 27 which determines whether repair is required for the tester 3, based on the occurrence history recorded in the occurrence history storage unit, and a controller 28 which controls the above components.

The occurrence history storage unit 26 stores occurrence history of the voltage component determined to be identified as the irregular signal by the determiner 13. The occurrence history may stores only the time when the irregular signal occurs but preferably includes other data related to the irregular signal such as waveform of the irregular signal.

The repair determiner 27 is configured to determine whether repair is required for the tester, based on the occurrence history of the irregular signal. The repair determiner 27 specifically is configured to calculate an occurrence frequency of the irregular signal from the occurrence history, and determine whether an electronic circuit of the tester has a defective part requiring repair. For example, the repair determiner 27 determines that the electronic circuit of the tester has the defective part if the occurrence frequency is more than a predetermined value. The result of determination by the repair determiner 27 is transmitted to the notifier 14 via the controller 28; the notifier 14 notifies the user of a message with whether repair is required for the tester 3. The repair determiner 27 may use not only the occurrence frequency but also other parameter. For example, the occurrence history storage unit 26 stores the peak voltage of the irregular signal, and the peak voltage is used as the other parameter.

The signal detecting apparatus 25 of the third embodiment has a function that determines whether repair is required for the tester 3, which causes the irregular signal to be detected, in addition to the functions of the signal detecting apparatus 1 of the first embodiment. The repair may be always required when the irregular signal is detected but such operation has a disadvantage in operational cost in actual use of the tester 3. If the tester 3 rarely causes the irregular signal, it is necessary to carefully check whether the DUT 2 when the irregular signal is detected deteriorates but it is not always necessary to repair the tester 3 promptly. In order to avoid the high operational cost, it may be preferable to continue use of this tester 3. On the other hand, if the tester 3 frequency causes the irregular signal, it is preferable to repair this tester 3 promptly or replace this tester 3 with new one in order to avoid reduction of the DUT product life.

Accordingly, the signal detecting apparatus 25 of the third embodiment can determine whether repair is required for the tester 3 by the occurrence history storage unit 26 and the repair determiner 27 in addition to the configuration of the signal detecting apparatus 1 of the first embodiment.

A fourth embodiment will be described below. A signal detecting system of the fourth embodiment is useful for detecting the irregular signals in plural testers in response to a situation where a large number of DUTs are to be tested in, for example, a semiconductor device manufacturing factory. The signal detecting system includes a plurality of signal detecting apparatuses each having the same configuration as the signal detecting apparatus described above, and a management server unifies management of the signal detecting apparatuses.

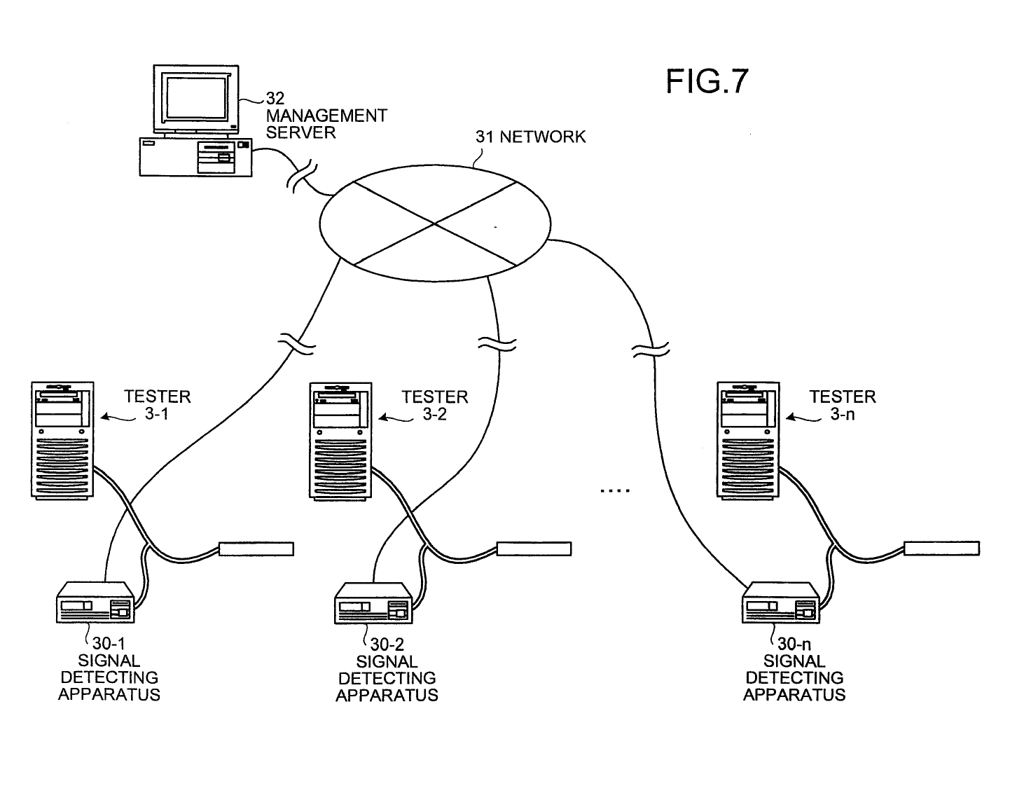

FIG. 7 is a block diagram of the signal detecting system of the fourth embodiment. Referring to FIG. 7, the signal detecting system applies plural testers 3-1 to 3-n (n: natural number more than one), and includes signal detecting apparatuses 30-1 to 30-n corresponding respectively to the testers 3-1 to 3-n, a network 31 to which the signal detecting apparatuses 30-1 to 30-n are connected, and a management server 32 which is connected to the network 31, obtains specific information from the signal detecting apparatuses 30-1 to 30-n via the network 31, and manages the signal detecting apparatuses 30-1 to 30-n.

The signal detecting apparatuses 30-1 to 30-n have the same basic configuration as the signal detecting apparatus according to any one of the first to third embodiments, and includes an appropriate interface for connecting to the network 31. As in the first to third embodiments, each of the signal detecting apparatuses 30-1 to 30-n is configured to extract a voltage component having more than a predetermined level from the power supply signal, calculate a time rate-of-change of the voltage component, calculate a time interval based on the time rate-of-change, and perform a determination process based on the time interval.

The network 31 enables data transmission between the signal detecting apparatuses 30-1 to 30-n and the management server 32. Various configurations such as local area network (LAN), wide area network (WAN), the Internet, and wireless LAN, if enabling the data transmission, are used as the network 31.

The management server 32 unifies management of the signal detecting apparatuses 30-1 to 30-n. The management server 32 is specifically configured to receive information from the signal detecting apparatuses 30-1 to 30-n, and notifies the user of occurrence of the irregular signal based on the received information when the irregular signal occurs in any of the testers 3-1 to 3-n.

Advantages of the signal detecting apparatus of the fourth embodiment are as follows. More than one signal detecting apparatus according to each of the first to third embodiments is generally used in a semiconductor device manufacturing factory. If the signal detecting apparatuses are standalone, the user is required to check whether the irregular signal is detected in respective signal detecting apparatuses, bearing a significant operational burden of the signal detecting apparatus.

By contrast, the signal detecting apparatus of the fourth embodiment has a configuration in which the management server 32 provided therein unifies, via the network 31, management of information obtained by the signal detecting apparatuses 30-1 to 30-n as well as notification of the irregular signal. In other words, the signal detecting system of fourth embodiment can provide the operational status of each of the signal detecting apparatuses 30-1 to 30-n to the user by checking not respective signal detecting apparatuses 30-1 to 30-n but only the operational status of the manage server 32. Accordingly, the signal detecting system has advantages that can reduce the administrative burden on the user and deal promptly with occurrence of the irregular signal in any of the testers 3-1 to 3-n corresponding respectively to the signal detecting apparatus 30-1 to 30-n.

The invention may be embodied in many different forms and but should not be construed as limited to the embodiments set forth herein; rather, additional advantages and modifications will readily occur to those skilled in the art. The first to fourth embodiments exemplify a power supply signal as an electronic signal containing the irregular signal to be detected, but the signal detecting apparatus according to the present invention may be configured to detect the irregular signal contained in a signal other than the power supply signal. For example, since a data signal or control signal used in the tester, when getting an irregular signal having a sudden change in voltage, may damage the electronic circuits of the tester, detecting such an irregular signal is advantageous.

The beginning and end of the time interval to be calculated, i.e., a given point in a period of positive time rate-of-change and a given point in a period of negative time rate-of-change, may be not the leading edge and trailing edge of a pulse signal, respectively. As can be seen from the mechanism of determination for the irregular signal, any time points during positive time rate-of-change and negative time rate-of-change may be used to calculate the time interval used for the determination. For example, the time interval between the time points of positive and negative peaks may be used for the determination.

A mechanism for comparing the designed pattern of an electronic signal such as a power supply signal with the pattern of the actual electronic signal may be provided in addition to the mechanism of determination. In the mechanism for comparing, when the actual pattern is different in peak position from the designed pattern, there is a strong possibility that the peak of the actual pattern is of the irregular signal; thus more accurate detection of irregular signal can be provided.

What is claimed is:

1. A signal detecting system comprising:
a plurality of signal detecting apparatuses corresponding respectively to a plurality of testers, each of the signal detecting apparatuses including
a component extractor extracting a voltage component whose absolute value is not less than a predetermined value from an electronic signal generated by a tester for testing an electric property of a device under test,
a rate-of-change calculator calculating a time rate-of-change of a level of the voltage component extracted by the component extractor, and
a determiner determining whether the voltage component is identified as an irregular signal having a sudden change in voltage, based on the time rate-of-change calculated by the rate-of-change calculator; and
a management server receiving results of determination by the signal detecting apparatuses, and notifying a user of at least one of the results which indicates that the voltage component is identified as the irregular signal.

2. The signal detecting system according to claim 1, wherein each of the signal detecting apparatuses further includes a defection estimator estimating a defective part of the tester based on an occurrence pattern of the voltage component determined to be identified as the irregular signal by the determiner.

3. The signal detecting system according to claim 2, wherein each of the signal detecting apparatus further includes an occurrence pattern database where a relation between occurrence patterns of irregular signals and defective parts of the tester is recorded, and
the defection estimator estimates a defective part based on the occurrence pattern of the voltage component determined to be identified as the irregular signal by the determiner with reference to the relation recorded in the occurrence pattern database.
